(19) United States
(12) Patent Application Publication
(10) Pub. No.: US 2026/0038626 A1
(43) Pub. Date: Feb. 5, 2026

(54) MEMORY DEVICE AND STORAGE DEVICE

(71) Applicant: Samsung Electronics Co., Ltd., Suwon-si (KR)

(72) Inventor: Sangin Park, Suwon-si (KR)

(21) Appl. No.: 19/176,730

(22) Filed: Apr. 11, 2025

(30) Foreign Application Priority Data
Aug. 5, 2024 (KR) 10-2024-0103619

(51) Int. Cl. G11C 29/56; G11C 5/14

(52) U.S. Cl. CPC G11C 29/56016; G11C 5/145; G11C 29/56012

(57) ABSTRACT

A storage device includes a memory package including memory chips; and a controller configured to control the memory chips, each of the memory chips including a memory region including memory blocks, and a peripheral circuit region including a charge pump circuit and a charge pump test circuit to measure an output voltage value of the charge pump circuit, and store an output voltage value measured using the charge pump test circuit as a first reference value, and wherein the controller is configured to provide a first monitoring request requesting a first monitoring using the charge pump test circuit to the memory chips, obtain a present output voltage value and the first reference value from the memory chips, and determine whether cracks are present in the memory chips based on the present output voltage value, the first reference value, and a relative position of the memory chips in the memory package.

### CROSS-REFERENCE TO RELATED APPLICATION(S)

This application claims benefit of priority under 35 U.S.C. § 119 to Korean Patent Application No. 10-2024-0103619, filed on Aug. 5, 2024, in the Korean Intellectual Property Office, the disclosure of which is incorporated herein by reference in its entirety.

### BACKGROUND

Example embodiments of the present disclosure relate to a memory device and a storage device including the memory device.

Generally, a semiconductor device may be formed in a repetitive pattern on a wafer of semiconductor material. A wafer may be cut into a large number of individual semiconductor dies, and each of the cut-out semiconductor dies may be packaged as a semiconductor device. During the cutting and packaging process, cracks may occur in the semiconductor device.

A semiconductor device may have microcracks not detected during pre-shipment testing. Microcracks may minimally affect operation of the semiconductor device, but depending on usage environment of a semiconductor device, cracks may increase, which may cause errors in operation of the semiconductor device.

### SUMMARY

An example embodiment of the present disclosure is to provide a memory device which may monitor whether cracks occur in the memory device while the memory device is used, and a storage device.

According to an example embodiment of the present disclosure, a storage device includes a memory package including a plurality of memory chips; and a controller configured to control the plurality of memory chips, wherein each of the plurality of memory chips include a memory region including a plurality of memory blocks, and a peripheral circuit region including a charge pump circuit and a charge pump test circuit configured to measure an output voltage value of the charge pump circuit, and is configured to store the output voltage value measured using the charge pump test circuit in a first memory block among the plurality of memory blocks as a first reference value, and wherein the controller is configured to provide a first monitoring request requesting a first monitoring using the charge pump test circuit to each of the plurality of memory chips, to obtain a present output voltage value and the first reference value from each of the plurality of memory chips, and to determine whether cracks are present in the plurality of memory chips based on the present output voltage value, the first reference value, and a relative position of each of the plurality of memory chips in the memory package.

According to an example embodiment of the present disclosure, a storage device includes a memory package including a plurality of memory chips; and a controller configured to control the plurality of memory chips, wherein each of the plurality of memory chips includes a memory region including a plurality of memory blocks, and a peripheral circuit region including a charge pump circuit and a charge pump test circuit configured to measure an output voltage value of the charge pump circuit, and wherein the controller is configured to provide a first monitoring request requesting a first monitoring using the charge pump test circuit for each of the plurality of memory chips, to obtain a plurality of output voltage values from the plurality of memory chips, and to detect whether cracks are present in the plurality of memory chips based on the plurality of output voltage values and relative positions of the plurality of memory chips in the memory package.

According to an example embodiment of the present disclosure, a memory device includes a memory region including a plurality of memory blocks; and a peripheral circuit region including a charge pump circuit configured to generate a driving voltage for controlling the plurality of memory blocks and a charge pump test circuit configured to measure an output voltage value of the charge pump circuit, wherein the charge pump test circuit is configured to operate the charge pump circuit during a predetermined number of clock cycles, to measuring a present output voltage value of the charge pump circuit, and to output a difference value between a reference value stored in a first memory block among the plurality of memory blocks and the present output voltage value to an external entity.

According to an example embodiment of the present disclosure, a memory device includes a memory region including a plurality of memory blocks; a peripheral circuit region including a peripheral circuit for controlling the plurality of memory blocks; a wiring structure disposed along at least a periphery of the peripheral circuit region; and a crack detecting circuit configured to input a test signal to a first node of the wiring structure, to receive the test signal output to a second node of the wiring structure, and to generate a propagation delay value between the first node and the second node, and wherein the crack detecting circuit is configured to generate a present propagation delay value and to output a difference value between a reference value stored in a first memory block among the plurality of memory blocks and the present propagation delay value to an external entity.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a block diagram illustrating a storage device according to an example embodiment of the present disclosure;

FIGS. 2A and 2B are diagrams illustrating a memory device according to an example embodiment of the present disclosure;

FIG. 3 is a block diagram illustrating a memory device according to an example embodiment of the present disclosure;

FIG. 4 is a diagram illustrating a voltage generator illustrated in FIG. 3;

FIG. 5 is a graph relating to operations of a charge pump test circuit illustrated in FIG. 4;

FIG. 6 is a diagram illustrating a memory device according to an example embodiment of the present disclosure;

FIG. 7 is a diagram illustrating a storage device according to an example embodiment of the present disclosure;

FIGS. 8 to 12 are diagrams illustrating operations of a storage device according to an example embodiment of the present disclosure; and

FIG. 13 is a diagram illustrating an electronic system to which a storage device may be applied according to an example embodiment of the present disclosure.

### DETAILED DESCRIPTION

Hereinafter, embodiments of the present disclosure will be described as follows with reference to the accompanying drawings.

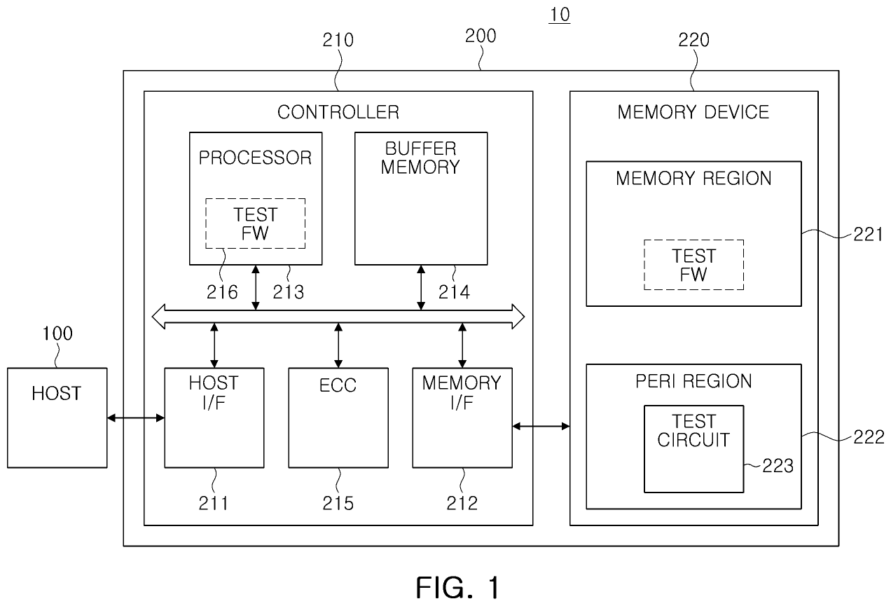

FIG. 1 is a block diagram illustrating a storage device according to an example embodiment.

The electronic system 10 may include a host 100 and a storage device 200. Also, the storage device 200 may include a controller 210 and a memory device 220.

The host 100 may include an electronic device, for example, a portable electronic device such as a mobile phone, an MP3 player, a laptop computer, or the like, or an electronic device such as a desktop computer, a game console, a TV, a projector, or the like. The host 100 may include at least one operating system (OS). The operating system may generally manage and control functions and operations of the host 100.

The storage device 200 may include storage media for storing data in response to a request from a host 100. As an example, the storage device 200 may include at least one of a solid state drive (SSD), an embedded memory, or a removable external memory.

When the storage device 200 is implemented as an SSD, the storage device 200 may comply with the NVMe (non-volatile memory express) standard. When the storage device 200 is implemented as an embedded memory or an external memory, the storage device 200 may comply with the UFS (universal flash storage) or eMMC (embedded multi-media card) standard. Each of the host 100 and the storage device 200 may generate a packet according to the adopted standard protocol and may transmit the packet.

The memory device 220 may maintain stored data even when power is not supplied. The memory device 220 may store data provided from a host 100 through a program operation, and may output data stored in the memory device 220 through a read operation.

When the memory device 220 includes a flash memory, the flash memory may include a 2D NAND memory or a 3D (or vertical) NAND (VNAND) memory. As another example, the storage device 200 may include various other types of nonvolatile memories. For example, the storage device 200 may include a magnetic RAM (MRAM), spin-transfer torque MRAM, conductive bridging RAM (CBRAM), ferroelectric RAM (FeRAM), phase RAM (PRAM), resistive RAM, and various other types of memory.

The controller 210 may control the memory device 220 in response to a request from a host 100. For example, the controller 210 may provide data read from the memory device 220 to a host 100 and may store data provided from a host 100 in the memory device 220. For these operations, the controller 210 may control read, program, and erase operations of the memory device 220.

The controller 210 may include a host interface 211, a memory interface 212, a processor 213, a buffer memory 214 and an error correction code (ECC) engine 215.

The host interface 211 may transmit a packet to and receive a packet from a host 100. A packet transmitted from a host 100 to a host interface 211 may include a command or data to be written in the memory device 220, and a packet transmitted from a host interface 211 to a host 100 may include a response to a command or data read out from the memory device 220.

The memory interface 212 may transmit data to be written in the memory device 220 to the memory device 220, or may receive data read out from the memory device 220. The memory interface 212 may be implemented to comply with a standard protocol such as toggle or open NAND flash interface (ONFI).

The processor 213 may execute firmware such as a flash translation layer (FTL) to control the storage device 200. The processor 213 may further include a working memory into which an FTL is loaded.

The FTL may perform various functions such as address mapping, wear-leveling, and garbage collection. An address mapping operation may be a technique for changing a logical address received from a host 100 into a physical address used to actually store data in the memory device 220. Wear-leveling may be a technique for preventing excessive deterioration of a specific block by allowing blocks in the memory device 220 to be used evenly, and may be implemented through a firmware technology for balancing erase counts of physical blocks, for example. Garbage collection may be a technique for securing available capacity in the memory device 220 by copying valid data of a block to a new block and erasing an existing block.

The buffer memory 214 may temporarily store data to be written in the memory device 220 or data read out from the memory device 220. The buffer memory 214 may be configured to be provided in the controller 210, but may also be disposed externally of the controller 210.

The ECC engine 215 may perform an error detecting and correcting function for readout data read out from the memory device 220. More specifically, the ECC engine 215 may generate parity bits for write data to be written in the memory device 220, and the generated parity bits may be stored in the memory device 220 together with the write data. When data is read from the memory device 220, the ECC engine 215 may correct an error in the readout data using the parity bits read out from the memory device 220 together with the readout data, and may output error-corrected readout data.

The memory device 220 may include a memory region 221 and a peripheral circuit region 222. The memory region 221 may include a plurality of memory blocks storing data, and the peripheral circuit region 222 may include peripheral circuits controlling the plurality of memory blocks.

Cracks in the memory device 220 may cause a defect in the memory device 220. Specifically, cracks in the memory device 220 may adversely affect electrical properties of the memory device 220. For example, when cracks reach a wiring layer of the memory device 220, cracks may increase leakage current.

When leakage current of the memory device 220 increases, a malfunction may occur in the memory device 220. For example, even when the memory device 220 performs charge pumping, it may be difficult to form a sufficient level of high voltage due to leakage current. Accordingly, it may be difficult to perform operations requiring high voltage, such as a program operation and an erase operation, normally in the memory device 220.

To preemptively select and discard a cracked memory device, a test may be performed on the memory device 220 before shipment. The memory device 220 may include a test circuit 223, and may provide a test mode in which a test may be performed on the memory device 220 externally before shipment using the test circuit 223.

For example, the memory device 220 may include a crack detecting circuit for detecting cracks occurring in the periphery of the memory device 220. For example, the crack detecting circuit may include a current path surrounding the memory region 221 and the peripheral circuit region 222, and may detect cracks by sensing electrical properties of a current path. The memory device 220 determined to be defective by the pre-test may not be provided to a user and may be discarded.

When the memory device 220 has microcracks, microcracks may not be detected in the pre-test using the crack detecting circuit. Accordingly, the memory device 220 having microcracks may not be discarded and may be provided to a user. However, after the memory device 220 is provided to a user, the size of cracks may grow due to factors such as temperature and humidity of usage environment.

Microcracks may insignificantly affect electrical properties of the memory device 220, but grown cracks may have a significant effect on electrical properties of the memory device 220. For example, when the charge pump does not normally form a program voltage due to increased leakage current of the memory device 220, it may be difficult to perform a program operation on the memory region 221 normally. The data programmed on the memory region 221 may be distorted to the extent that it may be difficult to recover even with the ECC engine 215.

According to an example embodiment, the memory device 220 may provide a function for monitoring whether cracks are present by executing a test mode using the test circuit 223 while being used by a user. For example, the memory device 220 may store a test firmware TEST FW including one or more instructions for controlling the test circuit 223 in the memory region 221. The test firmware may be loaded into the controller 210 while the memory device 220 is used, and may be executed by the controller 210. For example, the test firmware TEST FW stored in the memory region 221 of the memory device 220 may be loaded into the processor 213 of the controller 210 as test firmware 216, and the test firmware 216 may be executed by the controller 210.

According to an example embodiment, whether cracks are present in the memory device 220 may be monitored even after the memory device 220 is provided to the user. When the memory device 220 is determined to have cracks equal to or greater than a threshold level as a result of the monitoring, the use of the memory device 220 may be prohibited. Accordingly, cracks having grown due to the use environment of the memory device 220 may be detected, and abnormal operation of the storage device 200 caused by cracks may be prevented in advance.

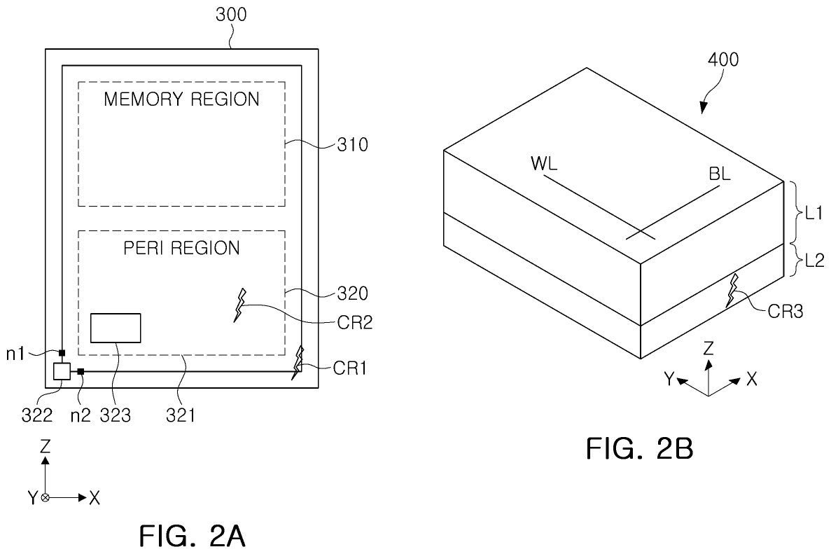

FIGS. 2A and 2B are diagrams illustrating a memory device according to an example embodiment.

Referring to FIG. 2A, a memory device 300 may include a memory region 310 and a peripheral circuit region 320. The memory device 300 may correspond to the memory device 220 described with reference to FIG. 1, and the memory region 310 and the peripheral circuit region 320 may correspond to the memory region 221 and the peripheral circuit region 222 described with reference to FIG. 1. In the example in FIG. 2A, the memory region 310 and the peripheral circuit region 320 may be formed adjacently on the X-Y plane.

The memory device 300 may include a crack detecting wiring 321 and a crack detecting circuit 322. The crack detecting wiring 321 may include wiring structures formed along the periphery of the memory region 310 and the peripheral circuit region 320.

The crack detecting circuit 322 may be connected to a first node n1 on a first end of the crack detecting wiring 321 and a second node n2 on a second end, and may perform a crack detecting test. For example, the crack detecting circuit 322 may input a test signal to the first node n1, may receive the test signal transferred from the first node n1 to the second node n2 through the crack detecting wiring 321 at the second node n2, and may measure a propagation delay value from the first node n1 to the second node n2.

When cracks CR1 are created in the region in which the crack detecting wiring 321 is formed, the wiring structure may be deformed or cut. Accordingly, when cracks CR1 are created, the propagation delay value may increase as compared to the case in which no cracks are present, or a test signal may not be transferred to the second node n2. The crack detecting circuit 322 may determine whether cracks are present in an edge region in which the crack detecting wiring 321 is formed by measuring the propagation delay value.

According to an example embodiment, the memory device 300 may be tested for whether cracks are present before shipment, and whether cracks are present may also be monitored using the crack detecting circuit 322 while the device is used. Herein, when a device “is used” or “being used,” it refers to use of the device after shipment from a device manufacturing facility (e.g., by an end user). For example, the propagation delay value measured by the crack detecting circuit 322 during a test before shipment may be stored as a reference value in a memory block of the memory region 310. Also, a present propagation delay value may be periodically measured by the crack detecting circuit 322 while the memory device 300 is used. Whether cracks are present may be determined based on a result of comparison between the present propagation delay value and the reference value.

The memory device 300 may further include a charge pump circuit and a charge pump test circuit 323. The charge pump circuit may generate a high voltage required for operation of the memory device 300, such as a program voltage and an erase voltage, by performing a charge pumping operation. High voltage may refer to a voltage level higher than a level of power voltage of the memory device 300.

The charge pump test circuit 323 may operate the charge pump circuit for a predetermined period, may measure an output voltage value of the charge pump circuit and may test charge pumping operation performance of the charge pump circuit.

According to an example embodiment, the memory device 300 may detect cracks CR2 of a central portion in which the crack detecting wiring 321 is not formed using the charge pump test circuit 323.

When the charge pump test passes in the test of the memory device 300 before shipment, the charge pumping performance of the charge pump circuit may be normal. However, when cracks CR2 are created in the peripheral circuit region 320 of the memory device 300, even when the charge pump circuit is normal, it may be difficult for the charge pump to generate sufficient high voltage due to leakage current occurring in the peripheral circuit region, and the charge pump test may fail.

Various peripheral circuits of the peripheral circuit region 320 may perform operations based on a common power voltage along with the charge pump circuit. Accordingly, even when cracks CR2 are created in a portion of circuits among the various peripheral circuits, leakage current may occur in the charge pump circuit, and the output voltage value of the charge pump circuit may decrease.

According to an example embodiment, whether cracks are present may be monitored using the charge pump test circuit 323 even while the memory device 300 is used. For example, the output voltage value measured by the charge pump test circuit 323 during the test before shipment may be stored as a reference value in the memory block of the memory region 310. Also, the present output voltage value may be periodically measured by the charge pump test circuit 323 while the memory device 300 is used. Whether cracks are present in the memory device 300 may be determined based on the result of comparison between the present output voltage value and the reference value.

Referring to FIG. 2B, a memory device 400 may include a first semiconductor layer L1 and a second semiconductor layer L2. The memory device 400 may correspond to the memory device 220 described with reference to FIG. 1.

The first semiconductor layer L1 may be stacked on the second semiconductor layer L2 in the Z-axis direction. In an example embodiment, the memory region 221 described with reference to FIG. 1 may be formed on the first semiconductor layer L1, and the peripheral circuit region 222 described with reference to FIG. 1 may be formed on the second semiconductor layer L2. For example, the second semiconductor layer L2 may include a lower substrate, and peripheral circuits may be formed on the second semiconductor layer L2 by forming a pattern for wiring semiconductor devices and devices, such as transistors, on the lower substrate.

After the circuits are formed on the second semiconductor layer L2, the first semiconductor layer L1 including the memory region may be formed. That is, the first semiconductor layer L1 may include an upper substrate, and a memory region may be formed in an upper portion of the upper substrate through support of the upper substrate.

Also, patterns for electrically connecting wordlines WL and bitlines BL formed in the memory region to peripheral circuits formed in the second semiconductor layer L2 may be formed in the first semiconductor layer L1.

The memory device 400 may have a structure in which the memory region and the peripheral circuit are disposed in the stacking direction (i.e., the Z-axis direction), that is, a cell-on-peri (CoP) structure. By disposing the circuits other than the memory region below the memory region, the CoP structure may effectively reduce the area occupied by the surface perpendicular to the stacking direction, and accordingly, the number of memory cells integrated in the memory device 400 may increase.

A crack detecting circuit may be formed around the peripheral circuit region of the memory device 400. The crack detecting circuit may detect cracks CR3 created on a side surface of the memory device 400. According to an example embodiment, the memory device 400 may monitor whether cracks are present on the side surface using the crack detecting circuit while being used.

The second semiconductor layer L2 of the memory device 400 may further include a charge pump circuit and a charge pump test circuit as described with reference to FIG. 2A. According to an example embodiment, the memory device 400 may monitor whether leakage current occurs in a peripheral circuit region using the charge pump test circuit while being used, and may determine whether cracks are present on a central portion in which the crack detecting circuit is not formed.

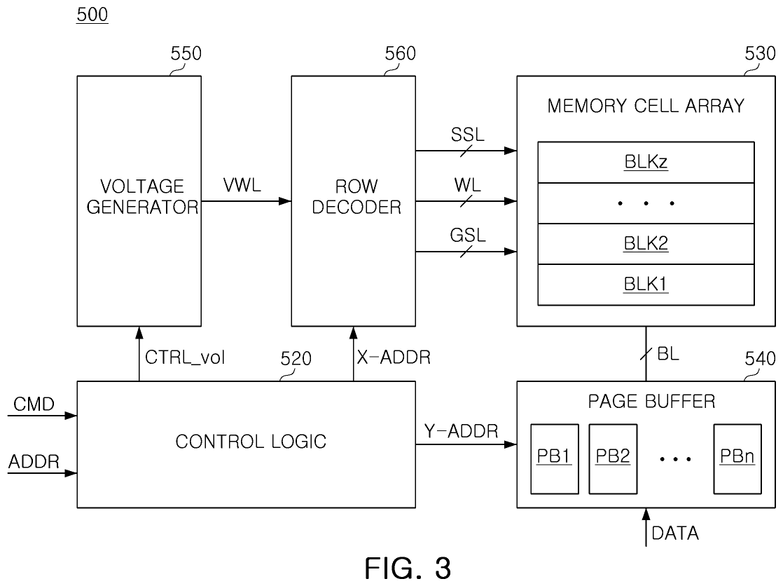

Hereinafter, circuits applicable to the memory device according to an example embodiment are described with reference to FIG. 3.

FIG. 3 is a block diagram illustrating a memory device according to an example embodiment.

FIG. 3 may be an example block diagram illustrating a nonvolatile memory. Referring to FIG. 3, a nonvolatile memory 500 may include a control logic circuit 520, a memory cell array 530, a page buffer 540, a voltage generator 550, and a row decoder 560. Although not illustrated in FIG. 3, the nonvolatile memory 500 may further include a memory interface circuit for receiving a command CMD and an address ADDR from an external entity and exchanging data DATA with an external entity, and may further include a column logic, a pre-decoder, a temperature sensor, a command decoder, an address decoder, or the like.

The control logic circuit 520 may generally control various operations in the nonvolatile memory 500. The control logic circuit 520 may output various control signals in response to a command CMD and/or an address ADDR from the memory interface circuit. For example, the control logic circuit 520 may output a voltage control signal CTRL_vol, a row address X-ADDR, and a column address Y-ADDR.

The memory cell array 530 may include a plurality of memory blocks BLK1 to BLKz (z is a positive integer), and each of the plurality of memory blocks BLK1 to BLKz may include a plurality of memory cells. The memory cell array 530 may be connected to the page buffer 540 through bitlines BL, and may be connected to the row decoder 560 through wordlines WL, string select lines SSL, and ground select lines GSL.

In an example embodiment, the memory cell array 530 may include a three-dimensional memory cell array, and the three-dimensional memory cell array may include a plurality of NAND strings. Each NAND string may include memory cells connected to wordlines stacked vertically on a substrate, respectively. U.S. Pat. Nos. 7,679,133, 8,553,466, 8,654,587, 8,559,235, and U.S. Patent Application Publication No. 2011/0233648 are incorporated herein by reference in their entireties. In an example embodiment, the memory cell array 530 may include a two-dimensional memory cell array, and the two-dimensional memory cell array may include a plurality of NAND strings disposed in the row and column directions.

The page buffer 540 may include a plurality of page buffers PB1 to PBn (n is an integer equal to or greater than 3), and the plurality of page buffers PB1 to PBn may be connected to memory cells through a plurality of bitlines BL, respectively. The page buffer 540 may select at least one bitline from among bitlines BL in response to the column address Y-ADDR. The page buffer 540 may operate as a write driver or a sense amplifier depending on an operation mode. For example, during a program operation, the page buffer 540 may apply a bitline voltage corresponding to data to be programmed to the selected bitline. During a readout operation, the page buffer 540 may sense data stored in the memory cell by sensing a current or voltage of the selected bitline.

The voltage generator 550 may generate various types of voltages for performing program, read, and erase operations based on the voltage control signal CTRL_vol. For example, the voltage generator 550 may generate a program voltage, a read voltage, a program verification voltage, an erase voltage, or the like, as a wordline voltage VWL.

The row decoder 560 may select one of a plurality of wordlines WL and one of a plurality of string select lines SSL in response to the row address X-ADDR. For example, during a program operation, the row decoder 560 may apply a program voltage and a program verification voltage to a selected wordline, and during a readout operation, the row decoder 560 may apply a readout voltage to a selected wordline.

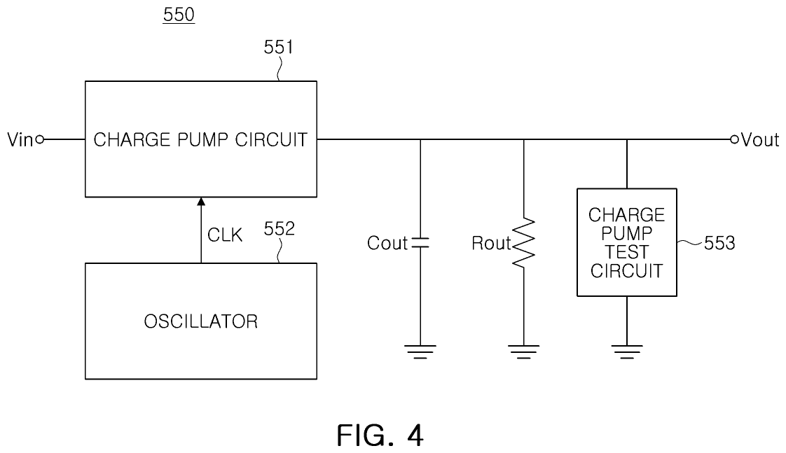

FIG. 4 is a diagram illustrating a voltage generator illustrated in FIG. 3.

Referring to FIG. 4, the voltage generator 550 may include a charge pump circuit 551, an oscillator 552, and a charge pump test circuit 553. The voltage generator 550 may correspond to the voltage generator 550 described with reference to FIG. 3.

The charge pump circuit 551 may receive an input voltage Vin and a clock signal CLK, and may generate an output voltage Vout based on the input voltage Vin and the clock signal CLK. For example, the charge pump circuit 551 may operate in one of a positive charge pump mode generating an output voltage Vout leveled up by the amount of the increase in the input voltage Vin of the clock signal CLK, and a negative charge pump mode generating an output voltage Vout leveled down by the amount of the decrease in the input voltage Vin of the clock signal CLK.

The charge pump circuit 551 may include a pumping capacitor portion and a signal controller. The pumping capacitor portion may include a pumping capacitor and may perform charge pumping according to a signal applied from the signal controller. The signal controller may apply a clock signal to the pumping capacitor portion. According to an example embodiment, the signal controller may include a clock driver. The signal controller may control the flow of current flowing in the pumping capacitor portion. According to an example embodiment, the signal controller may include a charge transfer switch and a high voltage transistor. According to an example embodiment, the charge transfer switch may be configured as a pass transistor.

The oscillator 552 may generate a clock signal CLK and may transfer the generated clock signal CLK to a clock driver in the signal controller of the charge pump circuit 551.

The voltage generator 550 may further include an output capacitor Cout and an output load Rout. The output capacitor Cout may charge the output voltage Vout output by the charge pump circuit 551 and may provide the output voltage Vout to the output load Rout.

The charge pump test circuit 553 may control operation of the charge pump circuit 551 and may measure performance of the charge pump by measuring the output voltage Vout output by the charge pump circuit 551.

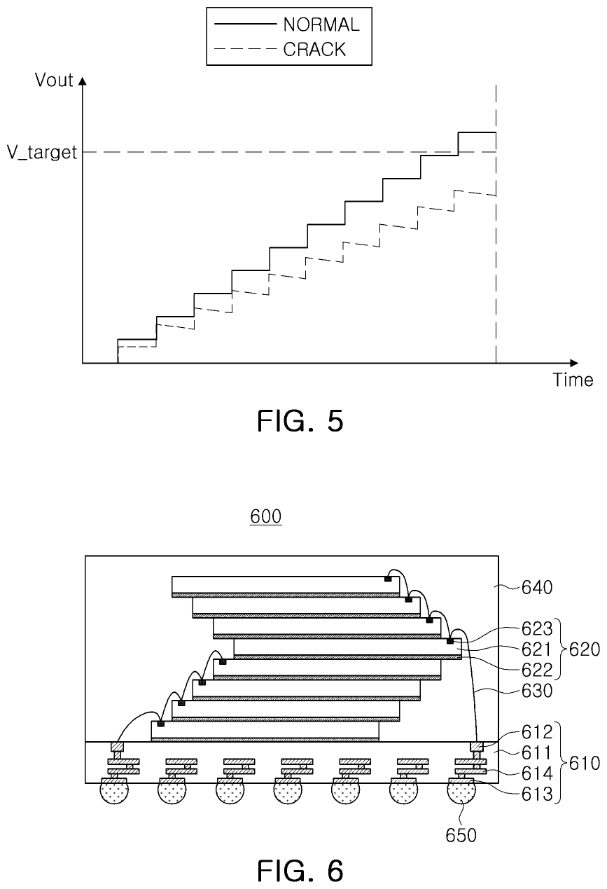

FIG. 5 is a graph relating to operations of a charge pump test circuit illustrated in FIG. 4.

FIG. 5 may be a diagram illustrating the output voltage Vout of the charge pump circuit over time. The charge pump test circuit 553 described with reference to FIG. 4 may perform a test of the charge pump circuit 551 by controlling the charge pump circuit 551 described with reference to FIG. 4 to perform a charge pumping operation for a predetermined period and measuring whether the output voltage Vout of the charge pump circuit 551 is equal to or greater than the target voltage V_target after the predetermined period has elapsed. For example, the predetermined period may be defined as the number of clock cycles of the clock signal CLK in FIG. 4.

When the charge pump circuit 551 has normal charge pumping performance, and the charge pump circuit 551 performs a predetermined number of charge pumping operations in response to the clock signal for a predetermined period, an output voltage Vout equal to or greater than the target voltage V_target may be output. For example, the target voltage V_target may include a high voltage such as a program voltage and an erase voltage.

When the charge pump circuit 551 is defective, a level of the output voltage Vout may decrease while the charge pumping operation is performed, and the level of the output voltage Vout may decrease below a level of the target voltage V_target after a predetermined period has elapsed.

During a test of the memory device before shipment, the charge pump test circuit 553 may generate an output voltage value representing the level of the output voltage Vout and may provide the output voltage value to the test device. For example, the output voltage value may be a digital signal. The test device may determine the charge pumping performance of the charge pump circuit 551 by comparing the output voltage value with the target voltage value corresponding to the level of the target voltage V_target.

When the charge pump circuit 551 is determined to have normal charge pumping performance during the test of the memory device before shipment, but the output voltage Vout level of the charge pump circuit 551 decreases while the memory device is used, it may be determined that the charge pump circuit 551 does not output the normal output voltage Vout due to increased leakage current while the memory device is used.

The leakage current of the memory device may increase due to various causes, including cracks further growing while the memory device is used. The storage device may include a plurality of memory devices, and the plurality of memory devices may be packaged in one or more memory packages.

According to an example embodiment, the storage device may periodically monitor the state of the memory device using a test circuit in the memory device while the memory device is used, and may determine whether cracks are present in the memory device based on the monitoring results and a relative position of the memory device in the memory package.

FIG. 6 is a diagram illustrating a memory device according to an example embodiment.

Referring to FIG. 6, a memory package 600 may include a package substrate 610, memory chips 620 on the package substrate 610, a connection structure 630 electrically connecting the memory chips 620 and the package substrate 610, a molding layer 640 covering the memory chips 620 and the connection structure 630 on the package substrate 610, and solder balls 650 for outputting a signal to an external entity or receiving an external signal in a lower portion of the package substrate 610.

The package substrate 610 may include an insulating layer 611, upper pads 612 formed on the insulating layer 611, lower pads 613 formed below the insulating layer 611, and conductive patterns 614 electrically connecting the upper pads 612 to the lower pads 613. The lower pads 613 may be in contact with the solder balls 650.

Each of the memory chips 620 may correspond to a memory device 300 described with reference to FIG. 2A or a memory device 400 described with reference to FIG. 2B. Each of the memory chips 620 may include a memory substrate 621, a memory structure 622, and input/output pads 623. The memory structure 622 may include a memory cell array circuit and a peripheral circuit.

In an example embodiment, the connection structure 630 may be a bonding wire electrically connecting the upper pads 612 to the input/output pads 623 of the memory chips 620. The memory chips 620 may be electrically connected to each other by the bonding wire method and may be electrically connected to the upper pads 612 of the package substrate 610.

In an example embodiment, the memory chips 620 may be electrically connected to each other by a connection structure including a through silicon via (TSV) instead of the connection structure 630 of a bonding wire-type.

The storage device may include memory chips 620 and a controller configured to control the memory chips 620. In an example embodiment, the memory chips 620 and the controller may be mounted in a single package. In an example embodiment, the controller may be mounted in a package separate from the memory package 600 in which the memory chips 620 are mounted, and the memory package 600 and the other package may be mounted on the main substrate.

The memory device described with reference to FIGS. 2A to 6 may provide a function for monitoring whether cracks in the memory device further grow while the memory device is used using a test circuit. For example, the memory device may store at least one instruction for performing monitoring using a test circuit in a memory block, and the instruction may be executed by the controller.

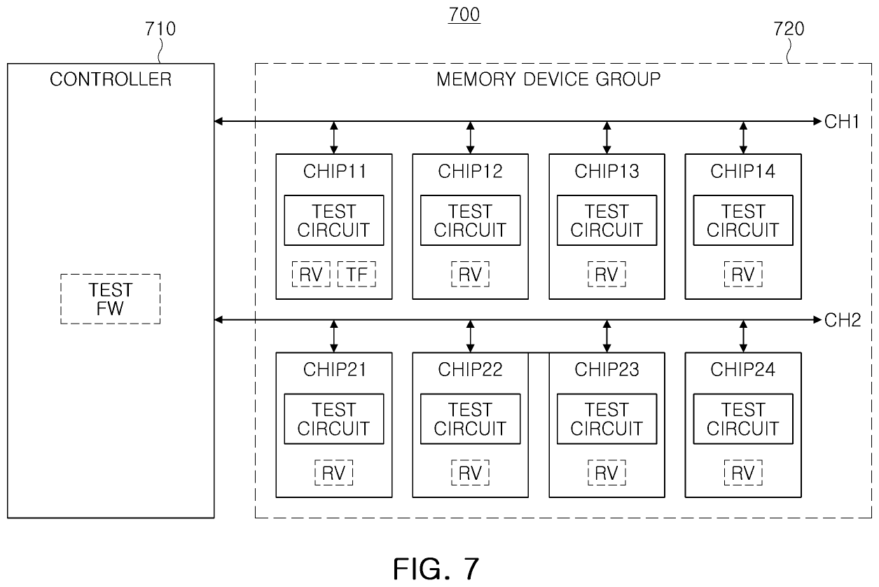

FIG. 7 is a diagram illustrating a storage device according to an example embodiment.

Referring to FIG. 7, a storage device 700 may include a controller 710 and a memory device group 720. The memory device group 720 may include a plurality of memory chips CHIP11-CHIP24. The memory chips CHIP11-CHIP24 may correspond to the memory devices described with reference to FIGS. 2A to 5 and the memory chips 620 described with reference to FIG. 6, respectively.

The controller 710 may communicate with the plurality of memory chips CHIP11-CHIP24 through channels CH1, CH2. For example, the channels CH1, CH2 may include a connection structure 630 described with reference to FIG. 6.

The memory chips CHIP11-CHIP24 may be packaged in one or more memory packages. Relative positions may be determined between the memory chips packaged in a memory package. The environments in which the memory chips are used may be different depending on the relative positions of the memory chips.

For example, the memory package may include a plurality of memory chips, including an uppermost memory chip positioned farthest from the package substrate and a lowermost memory chip positioned closest to the package substrate. The uppermost memory chip and the lowermost memory chip may be more affected by impacts applied to the memory package than the other intermediate memory chips. Accordingly, there may be possibility that cracks may be grown in the uppermost memory chip and the lowermost memory chip.

Each of the memory chips CHIP11-CHIP24 may include a test circuit TEST CIRCUIT. In an example embodiment, the test circuit TEST CIRCUIT may include at least a crack detecting circuit and a charge pump test circuit. The memory chips may be tested using the crack detecting circuit and the charge pump test circuit before shipment, and the memory chips passing the test may be included in the storage device 700 as the memory chips CHIP11-CHIP24. The test circuit TEST CIRCUIT may correspond to the test circuit 223, and the controller 710 may correspond to the controller 210 as described with reference to FIG. 2A.

According to an example embodiment, each of the memory chips CHIP11-CHIP24 may be tested before shipment, and the test result value may be stored as a reference value RV. For example, each of the memory chips CHIP11-CHIP24 may perform a test in response to a request from a test device, and may provide a test result value to the test device. Also, each of the memory chips CHIP11-CHIP24 may store the test result value as a reference value RV in a memory block in response to a request from the test device. For example, the memory block may be a special block such as a system block.

According to an example embodiment, at least one of the memory chips CHIP11-CHIP24 may store a test firmware TF including one or more instructions for monitoring whether cracks in the memory chip are further grown using the test circuit. In the example in FIG. 7, at least one memory chip CHIP11 may store the test firmware TF in a memory block such as a system block.

While the storage device 700 is used, the test firmware TF stored in at least one of the memory chips CHIP11-CHIP24 may be loaded into the working memory of the controller 710 as test firmware TEST FW, and may be executed periodically or in response to a request from a host.

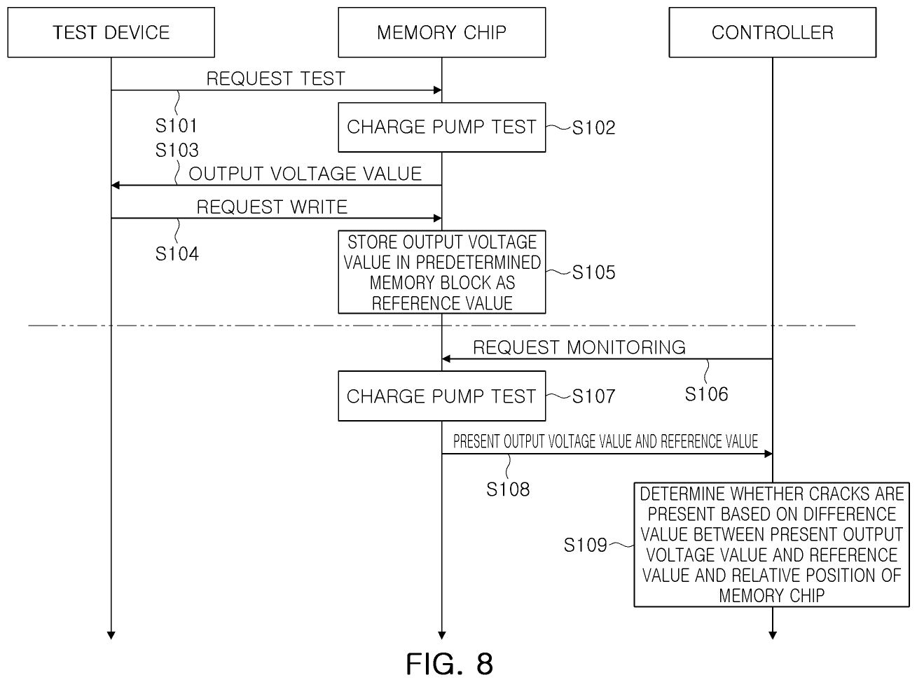

According to an example embodiment, the controller 710 may periodically monitor whether cracks are present in the memory chips CHIP11-CHIP24 by executing the test firmware TF stored in at least one of the memory chips CHIP11-CHIP24 and loaded into the working memory of the controller 710 as test firmware TEST FW. Hereinafter, various monitoring methods according to an example embodiment will be described with reference to FIGS. 8 to 12.

FIGS. 8 to 12 are diagrams illustrating operations of a storage device according to an example embodiment.

FIG. 8 may be a diagram illustrating interactions between a test device, a memory chip, and a controller for monitoring cracks. The memory chip in FIG. 8 may correspond to one of the memory chips CHIP11-CHIP24 described with reference to FIG. 7, and the controller in FIG. 8 may correspond to the controller 710 in FIG. 7.

Referring to FIG. 8, the crack monitoring operation may include operation S101 to operation S109. Operation S101 to operation S105 may be performed before release of the memory chip, and operation S106 to operation S109 may be performed after the memory chip is provided to a user in a state of being mounted on a storage device.

In operation S101, the test device may provide a test request to the memory chip. For example, the test request may be a charge pump test request using a charge pump test circuit.

In operation S102, the memory chip may perform a charge pump test in response to the test request. As described with reference to FIGS. 4 and 5, the memory chip may include a charge pump circuit and a charge pump test circuit. The charge pump test circuit may control the charge pump circuit to operate for a predetermined number of clock cycles, and may perform a charge pump test to measure an output voltage value of the charge pump circuit after the predetermined number of clock cycles have elapsed.

In operation S103, the memory chip may provide the output voltage value to the test device in response to the test request.

In operation S104, the test device may provide a write request for the output voltage value to the memory chip.

In operation S105, the memory chip may store the output voltage value as a reference value in a predetermined memory block in response to the write request.

The memory chip provided to the user in a state of being mounted in the storage device may be a memory chip determined as “pass” in the charge pump test of operation S102. For example, when the output voltage value satisfies a determined standard, the test circuit may determine the charge pump test result of the memory chip as “pass.” For example, when the output voltage value is equal to or higher than the target voltage V_target described with reference to FIG. 5, the test circuit may determine the charge pump test result of the memory chip as pass. The memory chips determined as “pass” in various tests including the charge pump test may be provided to a user in a state of being mounted in the storage device.

In operation S106, the controller may provide a monitoring request to the memory chip. For example, the controller may load the test firmware stored in the memory chip into the working memory at runtime. Also, the controller may provide the monitoring request by executing the test firmware as a background operation, or may provide the monitoring request by executing the test firmware in response to a power-off request from a host.

However, an example embodiment thereof is not limited thereto. For example, the controller may provide the monitoring request to the memory chip in response to a host command. A command for providing a monitoring request to the memory chip through the controller may be defined in advance between the storage device and the host using the storage device.

In operation S107, the memory chip may perform a charge pump test in response to the monitoring request. Similarly to operation S102, the charge pump test circuit may control the charge pump circuit to operate for a predetermined number of clock cycles, and may perform a charge pump test for measuring an output voltage value of the charge pump circuit after the predetermined number of clock cycles have elapsed.

In operation S108, the memory chip may provide the present output voltage value and the reference value stored in operation S105 to the controller in response to the monitoring request. In the example in FIG. 8, the monitoring value may refer to the output voltage value measured in operation S107.

In operation S109, the controller may determine whether cracks are present in the memory chip based on a difference value between the present output voltage value and the reference value, and a relative position of the memory chip.

According to an example embodiment, the controller may determine the detected memory chip as a cracked memory chip when a memory chip of which the difference value exceeds a threshold value is detected, and in a memory package in which the detected memory chip is mounted, the detected memory chip may be an uppermost memory chip or a lowermost memory chip.

Specifically, the difference value between the present output voltage value and the reference value of a memory chip exceeding the threshold value may indicate that the charge pump circuit had normal performance during a test of the memory chip before shipment and the leakage current of the memory chip was also at a normal level, but that the leakage current exceeded the normal level during monitoring.

Also, when the memory chip is an uppermost memory chip or a lowermost memory chip greatly affected by external influences as compared to other memory chips, it may be assumed that the leakage current has increased due to cracks growing in the memory chip.

According to an example embodiment, the storage device may perform monitoring of crack in the memory chip while the memory chip is used, by using a test circuit included in the memory chip for testing the memory chip before release of the memory chip.

Also, by performing the charge pump test, leakage current occurring in various peripheral circuits sharing a common power voltage with the charge pump circuit may be detected in the peripheral circuit region. Accordingly, the storage device may determine whether cracks are present in a wide range of regions, which may not be limited to the charge pump circuit region of the peripheral circuit. Cracks in the peripheral circuit region may increase leakage current in the peripheral circuit region and may also cause serious errors in data stored in the memory region.

According to an example embodiment, when a cracked memory chip is detected, the controller may prohibit use of the cracked memory chip. In an example embodiment, the controller may copy data stored in the cracked memory chip to a normal memory chip and may control not to store new data in the cracked memory chip. In an example embodiment, the controller may provide information about the cracked memory chip to a host. The host may perform measures to prevent access to the cracked memory chip, such as limiting capacity of data stored in a storage device including the cracked memory chip. The storage device may protect data stored in the storage device by prohibiting use of the cracked memory chip.

An example embodiment in which a memory chip performs a charge pump test in response to a monitoring request of the controller is described with reference to FIG. 8. However, an example embodiment thereof is not limited thereto. Hereinafter, a method for monitoring cracks in a storage device will be described with respect to an example in which a memory chip performs a charge pump test without relying on a monitoring request of the controller.

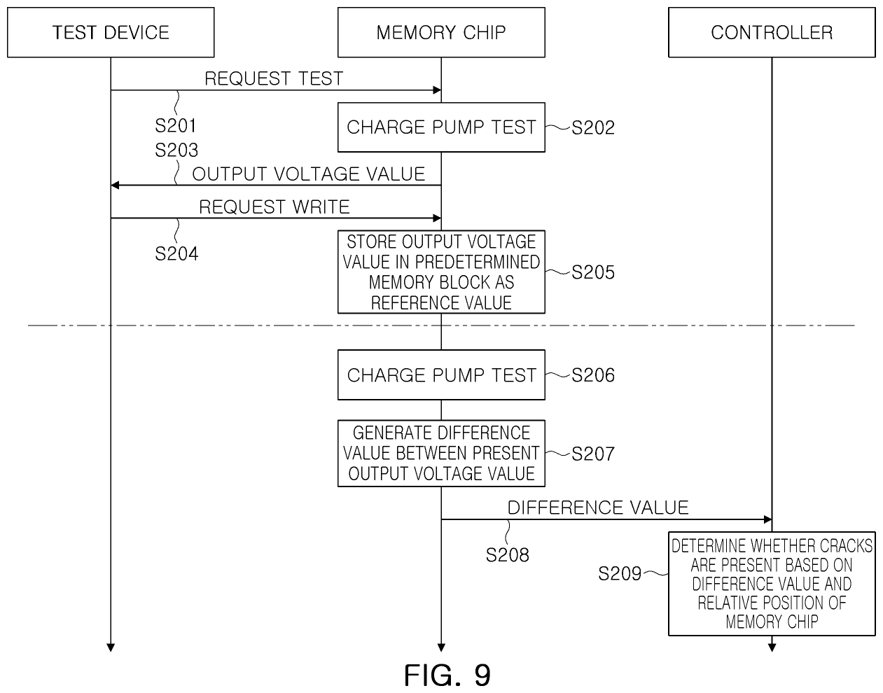

FIG. 9 may be a diagram illustrating interactions for monitoring cracks between a test device, a memory chip, and a controller. The memory chip and the controller in FIG. 9 may correspond to one of the memory chips CHIP11-CHIP24 and the controller 710, respectively, described with reference to FIG. 7.

Referring to FIG. 9, a crack monitoring operation may include operation S201 to operation S210. Operation S201 to operation S205 may be performed before release of the memory chip, and operation S206 to operation S209 may be performed after the memory chip is provided to a user in a state of being mounted in a storage device. Operation S201 to operation S205 in FIG. 9 are the same as operation S101 to operation S105, respectively, in FIG. 8, and the descriptions will not be repeated.

In operation S206, the memory chip may perform a charge pump test. The memory chip may start the charge pump test based on a control signal periodically generated by an on-chip circuit such as the control logic circuit 520 in FIG. 3. The charge pump test circuit and the charge pump test method were described with reference to FIG. 4 and FIG. 5.

In operation S207, the memory chip may obtain a present output voltage value from the charge pump test circuit, may obtain a reference value from a predetermined memory block, and may generate a difference value between the present output voltage value and the reference value. For example, the memory chip may further include a subtraction circuit for generating a difference value between the present output voltage value and the reference value.

In operation S208, the memory chip may provide the difference value to the controller. In operation S209, the controller may determine whether cracks are present in the memory chip based on the difference value and the relative position of the memory chip.

In an example embodiment, the memory chip may further calculate whether the difference value exceeds a predetermined threshold value, and may transmit a signal indicating whether the difference value exceeds the predetermined threshold value, and the controller may determine whether cracks are present in the memory chip based on the signal and the relative position of the memory chip.

When the controller detects a cracked memory chip, the use of the cracked memory chip may be prohibited as described with reference to operation S109 in FIG. 8.

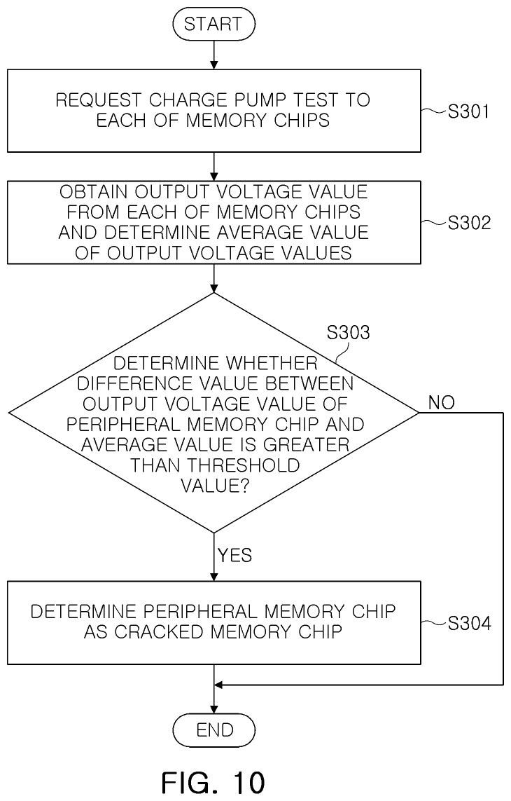

An example embodiment in which a cracked memory chip is detected by comparing a reference value stored during a test of the memory chip before shipment with a present output voltage value generated while being used is described with reference to FIGS. 8 and 9. However, an example embodiment thereof is not limited thereto. An example embodiment in which a cracked memory chip is detected by comparing present output voltage values of a plurality of memory chips included in a memory package will be described with reference to FIG. 10.

FIG. 10 may be a diagram illustrating operations of a controller according to an example embodiment. The controller of FIG. 10 may correspond to the controller 710 described with reference to FIG. 7, and may control memory chips CHIP11-CHIP24 described with reference to FIG. 7. Referring to FIG. 10, the crack monitoring operation may include operation S301 to operation S304.

In operation S301, the controller may request a charge pump test to each of the memory chips. For example, operation S301 may be performed as a background operation of the controller, may be performed in response to a power-off request from a host, or may be performed in response to a command from a host.

The memory chips may be included in a memory package. Each of the memory chips may perform a charge pump test in response to a request from the controller, and may output an output voltage value of a charge pump circuit.

In operation S302, the controller may obtain a plurality of output voltage values from the memory chips, and may determine an average value of the plurality of output voltage values obtained from the memory chips.

In operation S303, the controller may determine whether a difference value between an output voltage value of a peripheral memory chip and the average value is greater than a threshold value. The peripheral memory chip may be determined according to a relative position of the memory chips in the memory package. For example, the peripheral memory chip may include an uppermost memory chip and a lowermost memory chip of the memory package.

When a peripheral memory chip of which the difference value is greater than the threshold value is present (“YES” in operation S303), the controller may determine the peripheral memory chip as a cracked memory chip having cracks in a peripheral circuit region in operation S304.

Specifically, when a monitoring value of a memory chip deviates significantly from the average value, it may indicate that leakage current in the memory chip has significantly increased as compared to other memory chips. Also, when the memory chip is an uppermost memory chip or a lowermost memory chip greatly affected by an external influence as compared to other memory chips, it may be estimated that the leakage current has increased as cracks in the memory chip has further grown.

According to an example embodiment, when the controller detects a cracked memory chip, the use of the cracked memory chip may be prohibited as described with reference to operation S109 in FIG. 8.

When no peripheral chip of which the difference value is greater than the threshold value is present (“NO” in operation S303), the controller may complete the crack monitoring operation.

An example embodiment in which a cracked memory chip is detected using a charge pump test circuit is described with reference to FIGS. 8 to 10. According to an example embodiment, cracks in the memory chip may be detected using a crack detecting circuit while the memory chip is used. In an example embodiment, a memory chip having cracks in the peripheral circuit region may be detected using a charge pump test circuit, and a memory chip having cracks in the edge region of the memory chip may be detected using a crack detecting circuit.

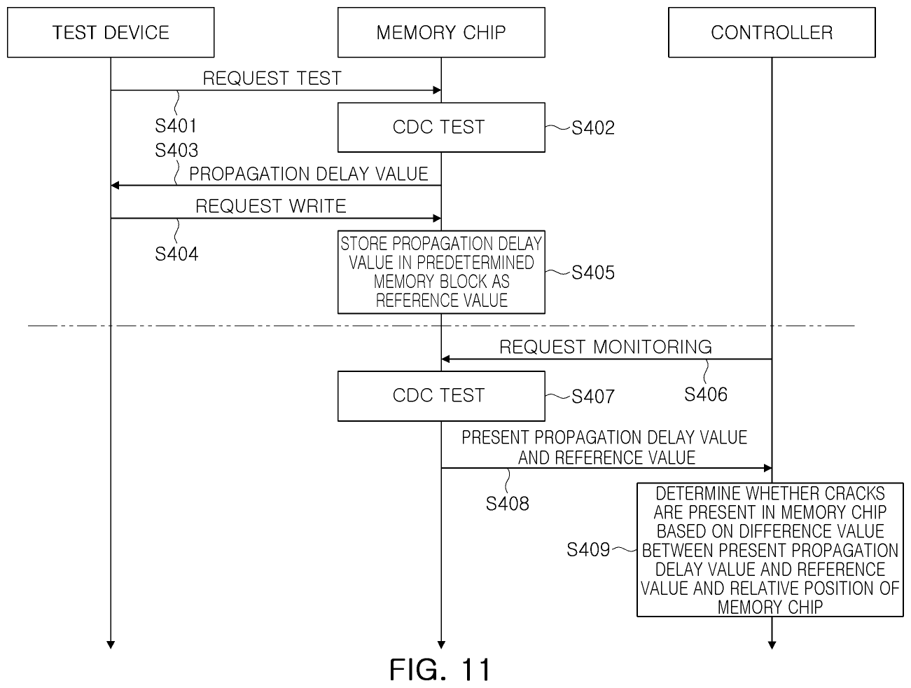

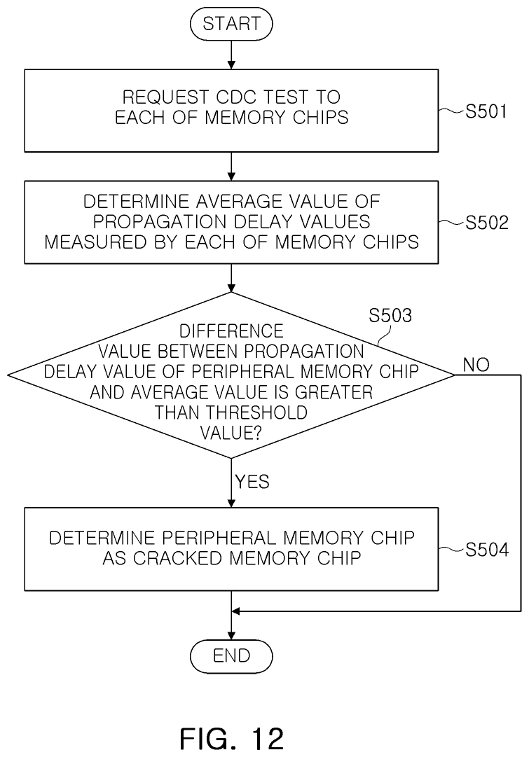

Hereinafter, example embodiments will be described with respect to an example in which a cracked memory chip is detected using a crack detecting circuit while the memory chip is used with reference to FIGS. 11 and 12.

FIG. 11 may be a diagram illustrating interactions for monitoring cracks between a test device, a memory chip, and a controller. The memory chip in FIG. 11 may correspond to one of the memory chips CHIP11-CHIP24 described with reference to FIG. 7, and the controller in FIG. 11 may correspond to the controller 710 in FIG. 7.

Referring to FIG. 11, the crack monitoring operation may include operation S401 to operation S409. Operations S401 to S405 may be performed before release of the memory chip, and operations S406 to S409 may be performed after the memory chip is provided to a user in a state in which the memory chip is mounted in the storage device.

In operation S401, the test device may provide a test request to the memory chip. For example, the test request may be a crack detection circuit (CDC) test request using a crack detecting circuit.

In operation S402, the memory chip may perform a CDC test in response to the test request. The crack detecting circuit may input a test signal to a first node (e.g., first node n1 of FIG. 2A) of the crack detecting wiring, may receive a test signal transferred from the first node to a second node (e.g., second node n2 of FIG. 2A) through the crack detecting wiring, and may be output by the second node. Also, the crack detecting circuit may measure the propagation delay time of the test signal in the first node and the second node, and may generate a propagation delay value corresponding to the propagation delay time. The propagation delay value may be a digital signal.

In operation S403, the memory chip may provide the propagation delay value to the test device in response to the test request.

In operation S404, the test device may provide a write request for the propagation delay value to the memory chip.

In operation S405, the memory chip may store the propagation delay value in a predetermined memory block as a reference value in response to the write request.

Operations S406 to S409 may be performed in a similar manner to operations S106 to S109 described with reference to FIG. 8, other than the configuration in which a CDC test is performed instead of a charge pump test.

In operation S406, the controller may provide a monitoring request to the memory chip, and in operation S407, the memory chip may perform a CDC test in response to the monitoring request. In operation S408, the memory chip may provide the present propagation delay value and the reference value to the controller in response to the monitoring request, and in operation S409, the controller may determine whether cracks are present in the memory chip based on a difference value between the present propagation delay value and the reference value and a relative position of the memory chip.

The method of performing crack monitoring using the CDC circuit of the memory chip while the memory chip is used is not limited to the method described with reference to FIG. 11.

For example, similarly to the example described with reference to FIG. 9, the memory chip may initiate a CDC test based on a control signal of an on-chip circuit such as the control circuit 520 in FIG. 3. Also, instead of providing the present propagation delay value and the reference value to the controller, the memory chip may provide the difference value of the present propagation delay value and the reference value to the controller, or may provide the signal indicating whether the difference value exceeds a threshold value to the controller.

Also, an example embodiment in which a cracked memory chip is detected by comparing propagation delay values of a plurality of the memory chips included in a memory package will be described with reference to FIG. 12.

FIG. 12 may be a diagram illustrating operations of a controller according to an example embodiment. The controller of FIG. 12 may correspond to the controller 710 described with reference to FIG. 7, and may control the memory chips CHIP11-CHIP24 described with reference to FIG. 7. Referring to FIG. 12, the crack monitoring operation may include operation S501 to operation S504.

Operation S501 to operation S504 may be performed in a similar manner to operation S301 to operation S304 described with reference to FIG. 10, other than the configuration in which a CDC test is performed instead of a charge pump test.

In operation S501, the controller may request a CDC test to each of the memory chips included in one memory package, and each of the memory chips may output a propagation delay value measured by a crack detecting circuit to the controller.

In operation S502, the controller may determine an average value of the propagation delay values measured by the memory chips.

In operation S503, the controller may determine whether a difference value between the propagation delay value of the peripheral memory chip and the average value is greater than the threshold value.

When a peripheral memory chip of which a difference value is greater than the threshold value is present (“YES” in operation S503), the controller may determine the peripheral memory chip as a cracked memory chip having cracks in the edge region in operation S504. When the controller detects the cracked memory chip, the controller may prohibit the use of the cracked memory chip.

When no peripheral memory chip of which a difference value is greater than the threshold value is present (“NO” in operation S503), the controller may complete the crack monitoring operation.

According to an example embodiment described with reference to FIGS. 1 to 12, the memory chip may support the test before release and also monitoring of cracks while being used using the charge pump test circuit and the crack detecting circuit. The storage device may monitor cracks while the memory chip is used by executing test firmware provided by the memory chip, and may detect cracks not detected during the test of the memory chip before release but which have further grown while the memory chip is used. Also, cracks in a region in which a crack detecting circuit is not formed may be detected using the charge pump test circuit.

According to an example embodiment, in the storage device, by detecting a cracked memory chip having cracks further grown while the memory chip is used and prohibiting the use of the cracked memory chip, the storage device may protect data stored in the storage device and may improve integrity of an electronic system including the storage device.

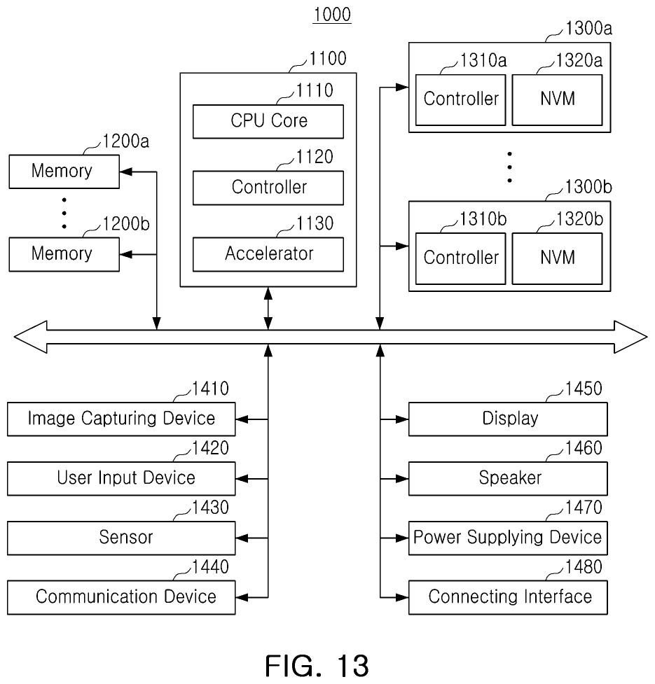

FIG. 13 may be a diagram illustrating an electronic system to which a storage device according to an example embodiment may be applied.

FIG. 13 may be a diagram illustrating a system 1000 to which a storage device according to an embodiment is applied. The system 1000 in FIG. 13 may be implemented as a mobile system, such as a mobile phone, a smart phone, a tablet personal computer, a wearable device, a healthcare device, or an Internet of Things (IoT) device. However, the system 1000 in FIG. 13 is not necessarily limited to a mobile system, and may also be implemented as a personal computer, a laptop computer, a server, a media player, or an automotive device, such as a navigation device.

Referring to FIG. 13, the system 1000 may include a main processor 1100, memories 1200a and 1200b and storage devices 1300a and 1300b, and may additionally include one or more of an image capturing device 1410, a user input device 1420, a sensor 1430, a communication device 1440, a display 1450, a speaker 1460, a power supplying device 1470, and a connection interface 1480.

The main processor 1100 may control overall operations of the system 1000, more specifically, may control operations of other components included in the system 1000. The main processor 1100 may be implemented as a general-purpose processor, a dedicated processor, or an application processor.

The main processor 1100 may include one or more CPU cores 1110, and may further include a controller 1120 for controlling the memories 1200a and 1200b and/or the storage devices 1300a and 1300b. According to an embodiment, the main processor 1100 may further include an accelerator 1130, which may be a dedicated circuit for high-speed data operations such as artificial intelligence (AI) data operations. The accelerator 1130 may include a graphics processing unit (GPU), a neural processing unit (NPU), and/or a data processing unit (DPU), and may be implemented as a chip physically independent from other components of the main processor 1100.

The memories 1200a and 1200b may be used as main memory device of system 1000, and may include volatile memory such as a SRAM and/or DRAM, but may also include nonvolatile memory such as a flash memory, PRAM and/or RRAM. The memories 1200a and 1200b may also be implemented in the same package as the main processor 1100.

The storage devices 1300a and 1300b may function as a nonvolatile storage device for storing data regardless of whether power is supplied, and may have a relatively large storage capacity as compared to the memories 1200a and 1200b. The storage devices 1300a and 1300b may include controllers 1310a and 1310b and nonvolatile memories (NVM) 1320a and 1320b for storing data under control of the controllers 1310a and 1310b. In example embodiments, each of the storage devices 1300a and 1300b may be one of the memory devices described with reference to FIGS. 2A to 6.

The nonvolatile memories 1320a and 1320b may include a flash memory of a 2-dimensional (2D) structure or a 3-dimensional (3D) V-NAND (vertical NAND) structure, and may also include other types of nonvolatile memory such as a PRAM and/or RRAM. The nonvolatile memories 1320a and 1320b may be implemented as memory chips, and the memory chips may be packaged in one or more memory packages.

The storage devices 1300a and 1300b may be included in the system 1000 in a state of being physically separated from the main processor 1100, or may be implemented in the same package as the main processor 1100. Also, the storage devices 1300a and 1300b may have a form such as an SSD (solid state device) or a memory card, and may be detachably connected to other components of the system 1000 through an interface such as the connection interface 1480 described later. A standard specification such as universal flash storage (UFS), embedded multi-media card (eMMC), or non-volatile memory express (NVMe) may be applied to the storage devices 1300a and 1300b, but an example embodiment thereof is not limited thereto.

According to an example embodiment, the storage devices 1300a and 1300b may detect a cracked memory chip and may prohibit use of the cracked memory chip by monitoring cracks using a charge pump test circuit and a crack detecting circuit included in the memory chip while the nonvolatile memories 1320a and 1320b are used. In an example embodiment, the storage devices 1300a and 1300b may provide information indicating whether cracks occur in the nonvolatile memories 1320a and 1320b to the main processor 1100. The main processor 1100 may perform measures such as limiting the amount of data stored in the storage devices 1300a and 1300b or replacing the storage devices 1300a and 1300b depending on whether cracks occur in the nonvolatile memories 1320a and 1320b.

The imaging capturing device 1410 may capture still images or moving images, and may be implemented as a camera, a camcorder, and/or a webcam.

The user input device 1420 may receive various types of data input from a user of the system 1000, and may be implemented as a touch pad, a keyboard, a mouse, and/or a microphone.

The sensor 1430 may sense various types of physical quantities obtained from an external entity of the system 1000, and may convert the sensed physical quantities into electrical signals. The sensors 1430 may be temperature sensors, pressure sensors, light sensors, position sensors, acceleration sensors, biosensors, and/or gyroscope sensors.

The communication device 1440 may perform signal transmission and reception between other devices externally of the system 1000 in accordance with various communication protocols. The communication device 1440 may be implemented to include an antenna, a transceiver, and/or a modem.

The display 1450 and the speaker 1460 may function as output devices for outputting visual information and auditory information to a user of the system 1000, respectively.

The power supplying device 1470 may appropriately convert power supplied from a battery (not illustrated) embedded in the system 1000 and/or an external power source and supply the power to each of the components of the system 1000.

The connection interface 1480 may provide a connection between the system 1000 and an external device connected to the system 1000 and exchanging data with the system 1000. The connection interface 1480 may be implemented by various interface methods such as advanced technology attachment (ATA), serial ATA (SATA), external SATA (e-SATA), small computer small interface (SCSI), serial attached SCSI (SAS), peripheral component interconnection (PCI), PCI express (PCIe), NVMe, IEEE 1394, universal serial bus (USB), secure digital (SD) card, multi-media card (MMC), eMMC, UFS, embedded universal flash storage (eUFS), compact flash (CF) card interface, or the like.

According to the aforementioned example embodiments, the memory device may provide a function of monitoring whether cracks are present in the memory device even using a crack detecting circuit provided for a test of the memory device before shipment while the memory device is used.

Also, the memory device may provide a function of monitoring whether cracks are present in a region in which the crack detecting circuit is not formed using a charge pump test circuit provided for a test of the memory device before shipment while the memory device is used.

Also, the storage device may detect cracks growing depending on usage environment of the memory device while the memory device is used, may prevent malfunction of the storage device due to use of a cracked memory device, and may protect data stored in the storage device.

While the example embodiments have been illustrated and described above, it will be configured as apparent to those skilled in the art that modifications and variations could be made without departing from the scope of the present disclosure as defined by the appended claims.

What is claimed is:

1. A storage device, comprising:
a memory package including a plurality of memory chips; and
a controller configured to control the plurality of memory chips,
wherein each of the plurality of memory chips includes a memory region including a plurality of memory blocks, and a peripheral circuit region including a charge pump circuit and a charge pump test circuit configured to measure an output voltage value of the charge pump circuit, and is configured to store the output voltage value measured using the charge pump test circuit in a first memory block among the plurality of memory blocks as a first reference value, and
wherein the controller is configured to provide a first monitoring request requesting a first monitoring using the charge pump test circuit to each of the plurality of memory chips, to obtain a present output voltage value and the first reference value from each of the plurality of memory chips, and to determine whether cracks are present in the plurality of memory chips based on the present output voltage value, the first reference value, and a relative position of each of the plurality of memory chips in the memory package.

2. The storage device of claim 1, wherein, when a memory chip of which a difference value between the present output voltage value and the first reference value is equal to or greater than a threshold value among the plurality of memory chips is an uppermost memory chip or a lowermost memory chip of the memory package, the controller determines the memory chip as a cracked memory chip.

3. The storage device of claim 1, wherein each of the plurality of memory chips further includes a wiring structure disposed along at least a periphery of the peripheral circuit region and a crack detecting circuit configured to output a test signal to a first node of the wiring structure, to receive the test signal to a second node of the wiring structure, and to generate a propagation delay value between the first node and the second node, and is configured to store the propagation delay value measured using the crack detecting circuit in the first memory block as a second reference value.

4. The storage device of claim 3, wherein the controller is configured to provide a second monitoring request requesting a second monitoring using the crack detecting circuit to each of the plurality of memory chips, to obtain a present propagation delay value and the second reference value from each of the plurality of memory chips, and to determine whether cracks are present in the plurality of memory chips based on the present propagation delay value, the second reference value, and the relative position of each of the plurality of memory chips in the memory package.

5. The storage device of claim 1, wherein, when a cracked memory chip is detected, the controller prohibits use of the cracked memory chip.

6. The storage device of claim 1, wherein, when a cracked memory chip is detected, the controller provides information about the cracked memory chip to a host.

7. The storage device of claim 1,
wherein each of the plurality of memory chips further includes an oscillator configured to provide a clock signal to the charge pump circuit, and
wherein the charge pump test circuit is configured to control the oscillator to provide the clock signal to the charge pump circuit during a predetermined number of clock cycles, and to measure an output voltage value of the charge pump circuit after the predetermined number of clock cycles are elapsed.

8. The storage device of claim 1, wherein at least one of the plurality of memory chips is configured to provide the first monitoring request to each of the plurality of memory chips, to obtain the present output voltage value and the first reference value from each of the plurality of memory chips, and to store test firmware including one or more instructions for determining whether cracks are present in the plurality of memory chips based on the present output voltage value, the first reference value and the relative position of each of the plurality of memory chips in the memory package in a second memory block among the plurality of memory blocks.

9. The storage device of claim 8, wherein the controller is configured to determine whether cracks are present in the plurality of memory chips by executing the test firmware as a background operation.

10. The storage device of claim 8, wherein the controller is configured to determine whether cracks are present in the plurality of memory chips by executing the test firmware in response to a power-off request from a host.

11. The storage device of claim 1, wherein the first reference value is stored in the first memory block before the memory package is shipped.

12. A storage device, comprising:
a memory package including a plurality of memory chips; and
a controller configured to control the plurality of memory chips,
wherein each of the plurality of memory chips includes a memory region including a plurality of memory blocks, and a peripheral circuit region including a charge pump circuit and a charge pump test circuit configured to measure an output voltage value of the charge pump circuit, and
wherein the controller is configured to provide a first monitoring request requesting a first monitoring using the charge pump test circuit for each of the plurality of memory chips, to obtain a plurality of output voltage values from the plurality of memory chips, and to detect whether cracks are present in the plurality of memory chips based on the plurality of output voltage values and relative positions of the plurality of memory chips in the memory package.

13. The storage device of claim 12, wherein the controller is configured to generate a first average value of the plurality of output voltage values, and to determine a memory chip of which a difference between an output voltage value and the first average value is greater than a first threshold value among uppermost or lowermost memory chips in the memory package among the plurality of memory chips as a cracked memory chip.

14. The storage device of claim 12, wherein each of the plurality of memory chips further includes a wiring structure disposed along at least a periphery of the peripheral circuit region, and a crack detecting circuit configured to output a test signal to a first node of the wiring structure, to receive the test signal to a second node of the wiring structure, and to generate a propagation delay value between the first node and the second node.

15. The storage device of claim 14, wherein the controller is configured to provide a second monitoring request requesting a second monitoring using the crack detecting circuit to each of the plurality of memory chips, to obtain a plurality of propagation delay values from the plurality of memory chips, and to detect whether cracks are present in the plurality of memory chips based on the plurality of propagation delay values and the relative positions of the plurality of memory chips in the memory package.

16. The storage device of claim 15, wherein a second average value of the plurality of propagation delay values is generated, and a memory chip of which a difference between an output voltage value and the second average value is equal to or greater than a second threshold value among uppermost or lowermost memory chips in the memory package among the plurality of memory chips is determined as a cracked memory chip.

17. A memory device, comprising:
a memory region including a plurality of memory blocks; and
a peripheral circuit region including a charge pump circuit configured to generate a driving voltage for controlling the plurality of memory blocks and a charge pump test circuit configured to measure an output voltage value of the charge pump circuit,
wherein the charge pump test circuit is configured to operate the charge pump circuit during a predetermined number of clock cycles, to measuring a present output voltage value of the charge pump circuit, and to output a difference value between a reference value stored in a first memory block among the plurality of memory blocks and the present output voltage value to an external entity.

18. The memory device of claim 17, wherein the charge pump test circuit is configured to output the difference value to the external entity in response to an external request.

19. The memory device of claim 17,
wherein the peripheral circuit region further includes a control circuit, and
wherein the charge pump test circuit is configured to output the difference value to the external entity in response to a control signal generated periodically by the control circuit.

20. The memory device of claim 17, wherein the plurality of memory blocks includes a second memory block configured to store test firmware including one or more instructions for determining whether cracks are present in the memory device based on the difference value.
